(19) United States
(12) Patent Application Publication
(10) Pub. No.: US 2024/0397716 A1
(43) Pub. Date: Nov. 28, 2024

(54) SEMICONDUCTOR DEVICE AND ELECTRONIC SYSTEM HAVING THE SAME

(71) Applicant: Samsung Electronics Co., Ltd., Suwon-si (KR)

(72) Inventors: Siyeong YANG, Suwon-si (KR); Yuyeon KIM, Suwon-si (KR); Chaeho KIM, Suwon-si (KR)

(73) Assignee: Samsung Electronics Co., Ltd., Suwon-si (KR)

(21) Appl. No.: 18/644,739

(22) Filed: Apr. 24, 2024

(30) Foreign Application Priority Data
May 26, 2023 (KR) 10-2023-0068620

(51) Int. Cl. H10B 43/27; G11C 16/04; H01L 25/065; H10B 41/10; H10B 41/27; H10B 41/35; H10B 41/41; H10B 43/10; H10B 43/35; H10B 43/40; H10B 80/00

(52) U.S. Cl. CPC H10B 43/27; G11C 16/0483; H01L 25/0657; H10B 41/10; H10B 41/27; H10B 41/35; H10B 41/41; H10B 43/10; H10B 43/35; H10B 43/40; H10B 80/00; H01L 2225/06506

(57) ABSTRACT

A semiconductor device includes a peripheral circuit structure including a plurality of circuits, and a cell array structure overlapping the peripheral circuit structure in a vertical direction. The cell array structure includes a common source line, a stack structure including a plurality of gate layers and a plurality of interlayer insulating layers which are alternately stacked on the common source line, and a plurality of channel structures in channel holes penetrating a memory cell area of the stack structure and connected to the common source line. Each of the plurality of channel structures includes a channel layer including an upper channel layer and a lower channel layer each having a single-crystal structure, and a crystal orientation of the upper channel layer is different from a crystal orientation of the lower channel layer.

### CROSS-REFERENCE TO RELATED APPLICATION

This application is based on and claims priority under 35 U.S.C. § 119 to Korean Patent Application No. 10-2023-0068620, filed on May 26, 2023, in the Korean Intellectual Property Office, the disclosure of which is incorporated by reference herein in its entirety.

### BACKGROUND

The present disclosure relates to semiconductor devices and electronic systems including the same, and more particularly to semiconductor devices including a non-volatile vertical memory device and electronic systems including the semiconductor devices.

In an electronic system requiring data storage, a semiconductor device capable of storing a large amount of data is required, and thus, methods for increasing data storage capacity of the semiconductor device have been studied. For example, as one of methods of increasing data storage capacity, a semiconductor device is suggested in which a vertical memory device includes memory cells that are three-dimensionally arranged instead of two-dimensionally arranged.

### SUMMARY

Embodiments of the inventive concepts provide a semiconductor device having high yield by simultaneously proceeding with the crystallization of a preliminary channel layer on both sides of the preliminary channel layer in a process of forming a channel structure in a vertical memory device, and limiting and/or preventing the occurrence of defects in a process of forming a channel layer.

Technical problems to be solved by embodiments of the inventive concepts are not limited to the above description, and other technical problems may be clearly understood by one of ordinary skill in the art from the descriptions provided hereinafter.

Embodiments of the inventive concepts provide a semiconductor device including a peripheral circuit structure including a plurality of circuits, and a cell array structure overlapping the peripheral circuit structure in a vertical direction. The cell array structure includes a common source line, a stack structure including a plurality of gate layers and a plurality of interlayer insulating layers which are alternately stacked on the common source line, and a plurality of channel structures in respective channel holes penetrating a memory cell area of the stack structure and connected to the common source line. Each of the plurality of channel structures includes a channel layer including an upper channel layer and a lower channel layer each having a single-crystal structure, and a crystal orientation of the upper channel layer is different from a crystal orientation of the lower channel layer.

Embodiments of the inventive concepts further provide a semiconductor device including a peripheral circuit structure including a plurality of circuits, and a cell array structure overlapping the peripheral circuit structure in a vertical direction. The cell array structure includes a common source line, a stack structure including a plurality of gate layers and a plurality of interlayer insulating layers which are alternately stacked on the common source line in a stair-shaped form, and a plurality of channel structures in respective channel holes penetrating a memory cell area of the stack structure and contacting the common source line. Each of the plurality of channel structures includes a channel layer including an upper channel layer and a lower channel layer each having a single-crystal structure, the upper channel layers of the plurality of channel structures contact the common source line, and crystal orientations of the upper channel layers of the plurality of channel structures are the same as.

Embodiments of the inventive concepts still further provide a semiconductor device including a peripheral circuit structure including a plurality of circuits and a first bonding metal pad, and a cell array structure overlapping the peripheral circuit structure in a vertical direction. The cell array structure includes a common source line having a single-crystal structure, a stack structure including a plurality of gate layers and a plurality of interlayer insulating layers which are alternately stacked on the common source line in a stair-shaped form, a plurality of channel structures in respective channel holes penetrating a memory cell area of the stack structure and contacting the common source line, and a second bonding metal pad spaced apart from the common source line with the stack structure and the plurality of channel structures therebetween. At least one of the plurality of circuits of the peripheral circuit structure is electrically connected to at least one of the plurality of gate layers of the cell array structure through the first bonding metal pad and the second bonding metal pad, each of the plurality of channel structures includes a channel layer including an upper channel layer and a lower channel layer each having a single-crystal structure, each upper channel layer contacts the common source line, each lower channel layer is spaced apart from the common source line with a respective upper channel layer therebetween, and a crystal orientation of each upper channel layer and a crystal orientation of the common source line are the same, and the crystal orientation of each upper channel layer is different from a crystal orientation of each lower channel layer.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to example embodiments;

FIG. 2 is a schematic perspective view of a semiconductor device according to example embodiments;

FIG. 3 is an equivalent circuit diagram showing a memory cell array of a semiconductor device, according to example embodiments;

FIG. 4 is a planar layout showing some components of a cell array structure of a semiconductor device, according to example embodiments;

FIG. 5 is a cross-sectional view showing some regions of each of a peripheral circuit structure and a cell array structure of a semiconductor device, according to example embodiments;

FIG. 6A is an enlarged cross-sectional view of a region “EX1” of FIG. 5;

FIG. 6B is an enlarged cross-sectional view of the region “EX1” of FIG. 5;

FIG. 7A is an enlarged cross-sectional view of a region “EX2” of FIG. 5;

FIG. 7B is an enlarged cross-sectional view of the region “EX2” of FIG. 5;

FIG. 8 shows an electronic system including a semiconductor device, according to example embodiments;

FIG. 9 is a perspective view of an electronic system including a semiconductor device, according to example embodiments;

FIG. 10 is a cross-sectional view of a semiconductor package including a semiconductor device, according to example embodiments; and

FIGS. 11A, 11B, 11C, 11D, 11E, 11F, 11G, 11H and 11I are cross-sectional views showing, in a process order, a method of manufacturing a semiconductor device, according to example embodiments.

### DETAILED DESCRIPTION

As the disclosure allows for various changes and numerous embodiments, particular embodiments will be shown in the drawings and described in detail in the written description. However, it is not intended to limit the present embodiments to specific embodiments.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

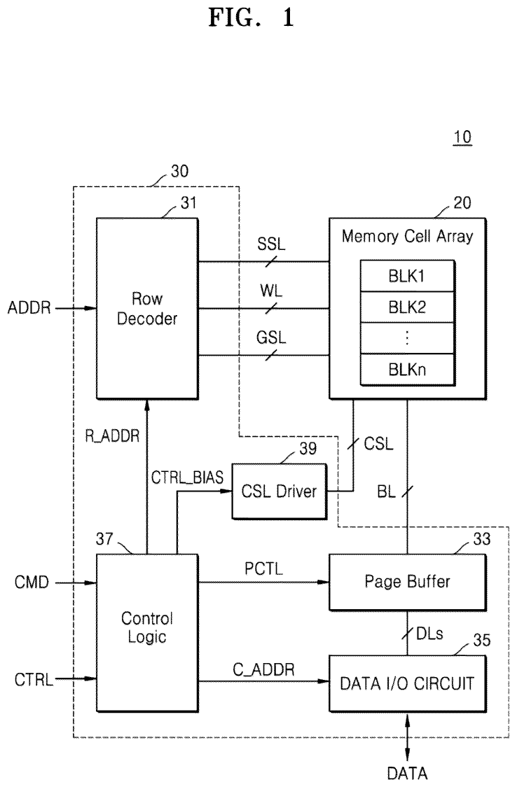

FIG. 1 is a block diagram of a semiconductor device according to example embodiments.

Referring to FIG. 1, a semiconductor device 10 may include a memory cell array 20 and a peripheral circuit 30.

The memory cell array 20 includes a plurality of memory cell blocks BLK1, BLK2, . . . , and BLKn. The memory cell blocks BLK1, BLK2, . . . , and BLKn may each include a plurality of memory cells. The memory cell blocks BLK1, BLK2, . . . , and BLKn may be connected to the peripheral circuit 30 through a bit line BL, a word line WL, a string selection line SSL, and a ground selection line GSL.

The memory cell array 20 may be connected to a page buffer 33 through the bit lines BL and to a row decoder 31 through the word lines WL, the string selection lines SSL, and the ground selection lines GSL. In the memory cell array 20, the memory cells respectively included in the memory cell blocks BLK1, BLK2, . . . , and BLKn may each be a flash memory cell. The memory cell array 20 may include a three-dimensional memory cell array. The three-dimensional memory cell array may include a plurality of NAND strings, and each NAND string may include a plurality of memory cells connected to the word lines WL vertically stacked.

The peripheral circuit 30 may include the row driver 31, the page buffer 33, a data input/output circuit 35, a control logic (e.g., a control logic circuit) 37, and a common source line driver 39. Although not shown, the peripheral circuit 30 may further include various circuits, for example, a voltage generation circuit configured to generate various voltages required to operate the semiconductor device 10, an error correction circuit configured to correct errors in data that is read from the memory cell array 20, an input/output interface, and the like.

The peripheral circuit 30 may receive an address ADDR, a command CMD, and a control signal CTRL from the outside of the semiconductor device 10 and receive/transmit data from/to a device outside the semiconductor device 10.

The configuration of the peripheral circuit 30 is described in detail as follows.

The row decoder 31 may select at least one of the memory cell blocks BLK1, BLK2, . . . , and BLKn in response to an external address ADDR and select a word line WL, a string selection line SSL, and a ground selection line GSL of the selected memory cell block. The row decoder 31 may transmit a voltage for performing a memory operation on the word line WL of the selected memory cell block.

The page buffer 33 may be connected to the memory cell array 20 through the bit lines BL. The page buffer 33 may function as a write driver during a program operation and thus may apply, to the bit line BL, a voltage according to data DATA to be stored in the memory cell array 20, and the page buffer 33 may function as a sense amplifier during a read operation and thus may detect data DATA stored in the memory cell array 20. The page buffer 33 may operate according to a control signal PCTL provided from the control signal 37.

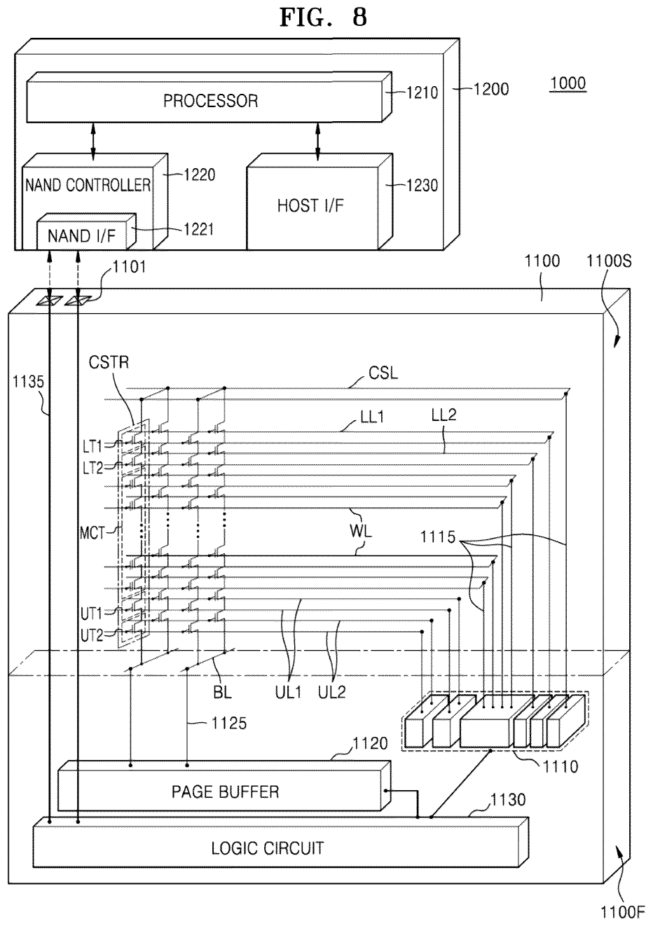

The data input/output circuit 35 may be connected to the page buffer 33 through data lines DLs. During the program operation, the data input/output circuit 35 may receive data DATA from a controller (e.g., 1200, see FIG. 8) and provide program data DATA to the page buffer 33 based on a column address C_ADDR provided from the control logic 37. During the read operation, the data input/output circuit 35 may provide the controller (e.g., 1200, see FIG. 8) with the read data DATA that is stored in the page buffer 33, based on a column address C_ADDR provided from the control logic 37. The data input/output circuit 35 may transmit an input address or command to the control logic 37 or the row decoder 31.

The control logic 37 may receive the command CMD and the control signal CTRL from the controller (e.g., 1200, see FIG. 8). The control logic 37 may provide a row address R_ADDR to the row decoder 31 and a column address C_ADDR to the data input/output circuit 35. The control logic 37 may generate a variety of internal control signals used in the semiconductor device 10, in response to the control signal CTRL. For example, the control logic 37 may control a voltage level provided to the word line WL and the bit line BL during a memory operation, such as a program operation or an erase operation.

The common source line driver 39 may be connected to the memory cell array 20 through a common source line CSL. The common source line driver 39 may apply a common source voltage (e.g., a power voltage) or a ground voltage to the common source line CSL, according to the control of the control logic 37 responsive to a control bias signal CTRL_BIAS.

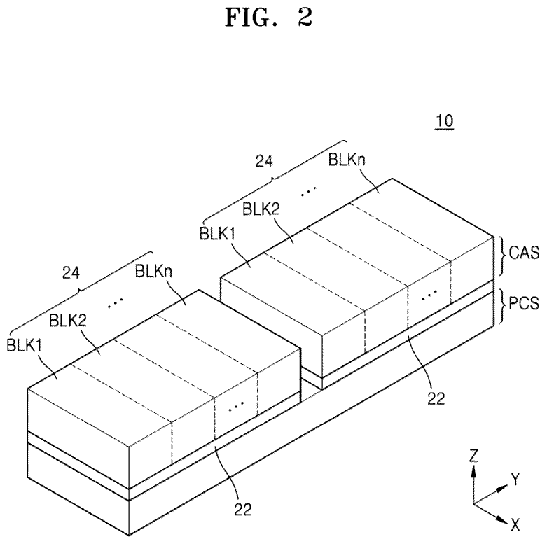

FIG. 2 is a schematic perspective view of a semiconductor device according to example embodiments.

Referring to FIG. 2, the semiconductor device 10 includes a peripheral circuit structure PCS and a cell array structure CAS which overlap each other in a vertical direction (a Z direction).

The cell array structure CAS may include the memory cell array (e.g., 20, see FIG. 1), and the peripheral circuit structure PCS may include the peripheral circuit (e.g., 30, see FIG. 1).

Connection structures 22 may be arranged between the cell array structure CAS and the peripheral circuit structure PCS. The cell array structure CAS and the peripheral circuit structure PCS may be stacked through the connection structure 22 in the vertical direction (the Z direction). The connection structure 22 may establish a physical connection and an electrical connection between the cell array structure CAS and the peripheral circuit structure PCS. The electrical connection and data transmission between the cell array structure CAS and the peripheral circuit structure PCS may be enabled through the connection structure 22.

The connection structure 22 may include a plurality of connection portions for electrically connecting the cell array structure CAS to the peripheral circuit structure PCS. The connection portions may include a metal-metal bonding structure, a through silicon via (TSV), a back via stack (BVS), a eutectic bonding structure, a ball grid array (BGA) bonding structure, a plurality of wire lines, a plurality of contact plugs, and a combination thereof. For example, the metal-metal bonding structure may include copper (Cu), aluminum (Al), tungsten (W), or a combination thereof.

The cell array structure CAS may include a plurality of tiles 24. Each tile 24 may include the memory cell blocks BLK1, BLK2, . . . , and BLKn. The memory cell blocks BLK1, BLK2, . . . , and BLKn may each include a plurality of memory cells that are three-dimensionally arranged.

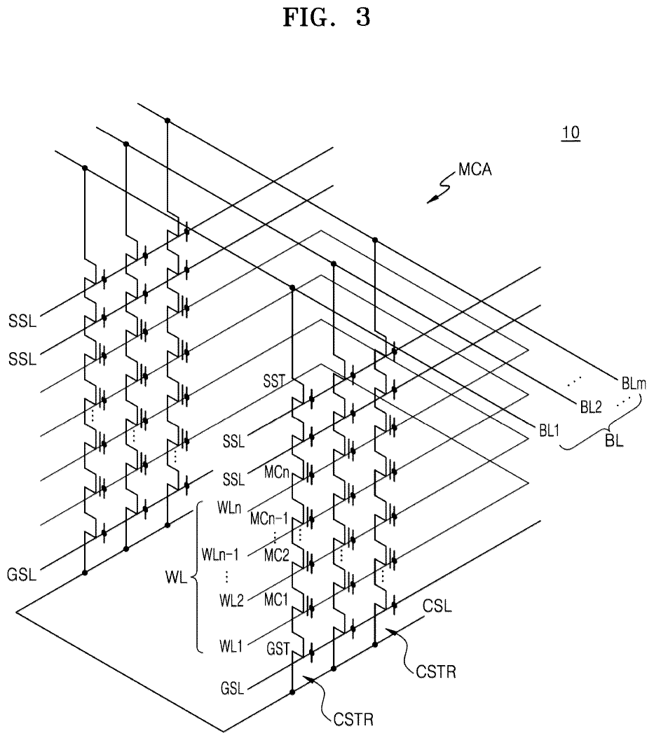

FIG. 3 is an equivalent circuit diagram showing a memory cell array of a semiconductor device, according to example embodiments.

FIG. 3 shows an example equivalent circuit diagram of a vertical NAND flash memory device having a vertical channel structure.

In the semiconductor device 10, a memory cell array MCA may include a plurality of memory cell strings CSTR. The memory cell array MCA may include bit lines BL, word lines WL, at least one string selection line SSL, at least one ground selection line GSL, and a common source line CSL.

The memory cell strings CSTR may be formed between the bit lines BL and the common source line CSL. The drawing shows that each memory cell string CSTR includes two string selection lines SSL, but one or more embodiments are not limited thereto. For example, each memory cell string CSTR may include one string selection line SSL.

Each memory cell string CSTR may include a string selection transistor SST, a ground selection transistor GST, and a plurality of memory cell transistors MC1, MC2, . . . , MCn−1, and MCn. A drain area of the string selection transistor SST may be connected to the bit line BL, and a source area of the ground selection transistor GST may be connected to the common source line CSL. The common source line CSL may be an area where source areas of ground selection transistors GST are commonly connected.

The string selection transistor SST may be connected to the string selection line SSL, and the ground selection transistor GST may be connected to the ground selection line GSL. The memory cell transistors MC1, MC2, . . . , MCn−1, and MCn may be connected to corresponding word lines WL1, WL2, . . . , WLn−1, and WLn, respectively. The bit lines BL may include bit line BL1, BL2, . . . and BLm.

Each of the memory cell blocks BLK1, BLK2, . . . , and BLKn described above with reference to FIGS. 1 and 2 may include the memory cell array MCA including the circuit configuration described with reference to FIG. 3.

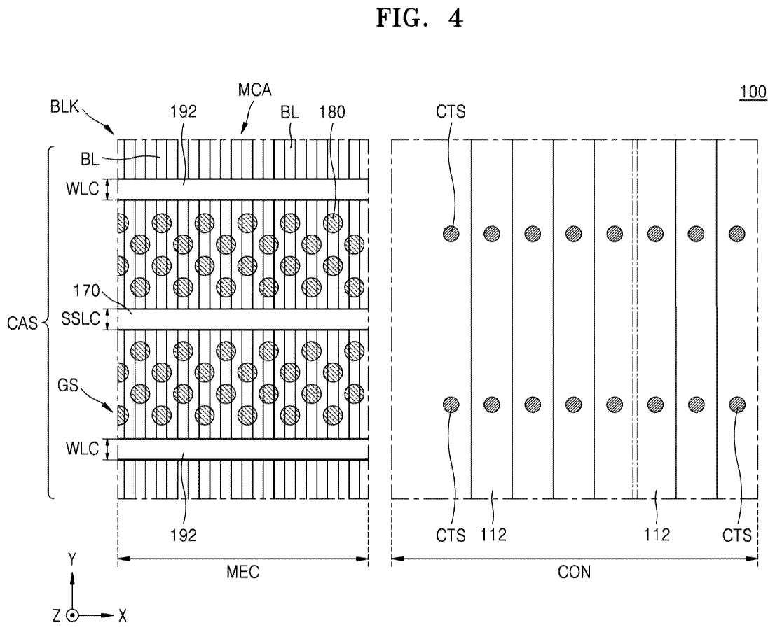

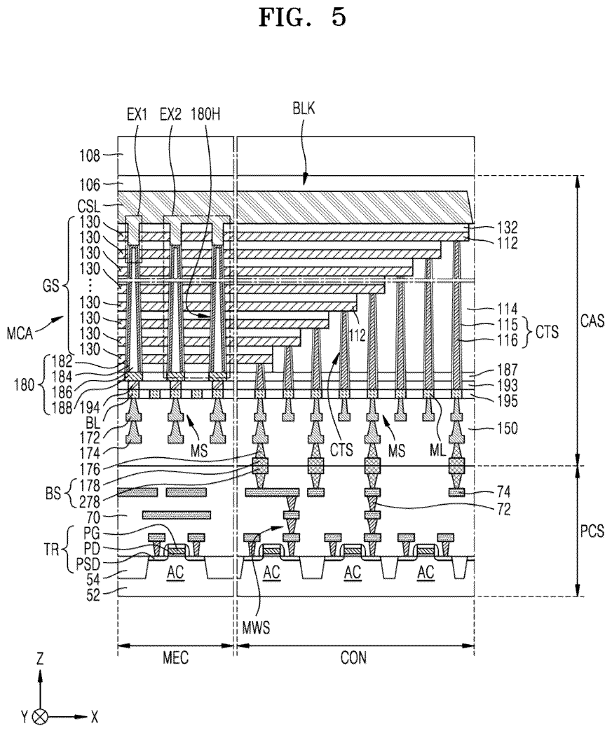

FIG. 4 is a planar layout showing some components of a cell array structure of a semiconductor device, according to example embodiments. FIG. 5 is a cross-sectional view showing some regions of each of a peripheral circuit structure and a cell array structure of a semiconductor device, according to example embodiments.

Referring to FIGS. 4 and 5, a semiconductor device 100 may include a cell array structure CAS and a peripheral circuit structure PCS which overlap each other in a vertical direction (a Z direction). The cell array structure CAS may include a memory cell area MEC, in which the memory cell array MCA is arranged, and a connection area CON located on one side of the memory cell area MEC in a first horizontal direction (an X direction).

As shown in FIG. 4, in the cell array structure CAS, a plurality of word line cut areas WLC may extend in the first horizontal direction (the X direction). The word line cut areas WLC may limit widths of gate stacks GS in a second horizontal direction (a Y direction). The word line cut areas WLC may be filled with word line cut structures 192. The word line cut structure 192 may include an insulating layer, polysilicon, a metal layer, or a combination thereof. In some embodiments, the word line cut structure 192 may include a silicon oxide layer, a silicon nitride layer, a polysilicon layer, a tungsten layer, or a combination thereof, but example embodiments are not limited thereto.

In example embodiments, the semiconductor device 100 may have a chip-to-chip (C2C) structure. The C2C structure may be obtained by forming the cell array structure CAS on a first wafer and the peripheral circuit structure PCS on a second wafer, separate from the first wafer, and then bonding the cell array structure CAS to the peripheral circuit structure PCS.

For example, the bonding process may include a method of electrically connecting a plurality of first bonding metal pads 178, which are formed on a lowermost metal layer of the cell array structure CAS, to a plurality of second bonding metal pads 278, which are formed on an uppermost metal layer of the peripheral circuit structure PCS. In example embodiments, when the first bonding metal pads 178 and the second bonding metal pads 278 each include Cu, the above bonding process may be Cu—Cu bonding. In example embodiments, the first bonding metal pads 178 and the second bonding metal pads 278 may each include Al or W.

The peripheral circuit structure PCS may include a substrate 52, a plurality of circuits formed on the substrate 52, and a multilayered wire structure MWS configured to interconnect the circuits or connect the circuits to components in the memory cell area MEC of the cell array structure CAS.

The substrate 52 may be a semiconductor substrate. For example, the substrate 52 may include silicon (Si), germanium (Ge), or SiGe. In the substrate 52, active areas AC may be defined by a device isolation layer 54. A plurality of transistors TR for forming the circuits may be formed above the active areas AC. Each transistor TR may include a gate dielectric layer PD and a gate PG that are sequentially stacked on the substrate 52, and a plurality of ion implantation areas PSD formed in the active areas AC on both sides of the gate PG. Each ion implantation area PSD may form a source area or a drain area of the transistor TR.

The multilayered wire structure MWS included in the peripheral circuit structure PCS may include a plurality of contact plugs 72 and a plurality of conductive lines 74. At least some of the conductive lines 74 may be electrically connected to the transistors TR. The contact plugs 72 may be configured to connect the transistors TR to selected ones of the conductive lines 74. The transistors TR and the multilayered wire structure MWS included in the peripheral circuit structure PCS may be covered by an interlayer insulating layer 70.

In example embodiments, the contact plugs 72 and the conductive lines 74 included in the peripheral circuit structure PCS may each include W, Al, Cu, or a combination thereof, but example embodiments are not limited thereto. The device isolation layer 54 may include a silicon oxide layer, a silicon nitride layer, or a combination thereof. The interlayer insulating layer 70 may include a silicon oxide layer, a silicon nitride layer, or a combination thereof.

The circuits included in the peripheral circuit structure PCS may include various circuits included in the peripheral circuit 30 of FIG. 1, for example, the row driver 31, the page buffer 33, the data input/output circuit 35, the control logic 37, and the common source line driver 39. In example embodiments, the peripheral circuit structure PCS may further include unit devices, such as a resistor and a capacitor. Each transistor TR may be electrically connected to the memory cell array MCA of the cell array structure CAS through the multilayered wire structure MWS including the contact plugs 72 and the conductive lines 74. The multilayered wire structure MWS may include a plurality of contact structures CTS arranged in the connection area CON of the cell array structure CAS.

The cell array structure CAS may include the common source line CSL, stack structures, and channel structures 180.

The cell array structure CAS may include the memory cell array MCA arranged between the peripheral circuit structure PCS and the common source line CSL. The gate stack GS, in which a plurality of gate layers 130 are stacked, may be arranged between the peripheral circuit structure PCS and the common source line CSL in the memory cell area MEC and the connection area CON.

The common source line CSL may function as a source area in which a current is supplied to the memory cell arrays MCA formed in the cell array structure CAS. The common source line CSL may have a single-crystal structure. In detail, the common source line CSL may include a semiconductor material having a single-crystal structure and not containing carbon. In example embodiments, the common source line CSL may include single-crystal silicon that does not contain carbon. In example embodiments, the common source line CSL may include single-crystal silicon doped with n-type impurities. In example embodiments, a Miller index of a crystal orientation of the common source line CSL may be [1, 1, 1]. The term “crystal orientation” used in the present specification may refer to a direction in which a crystal structure is oriented with respect to an upper surface of a polycrystalline structure or a single-crystal structure.

In example embodiments, the common source line CSL may include a semiconductor material, such as a Group IV semiconductor material, a Group III-V semiconductor material, or a Group II-VI semiconductor material. For example, the common source line CSL may include at least one of Si, Ge, SiGe, gallium arsenide (GaAs), indium gallium arsenide (GaAs), AlGaAs, and a combination thereof. The common source line CSL may include a semiconductor doped with n-type impurities.

The common source line CSL may be covered by an insulating layer 106 and a protective layer 108. The insulating layer 106 may include a silicon oxide layer, and the protective layer 108 may include a polyimide-based material layer including, e.g., photosensitive polyimide (PSPI), but example embodiments are not limited thereto.

FIG. 5 shows that the common source line CSL is integrally formed over the memory cell area MEC and the connection area CON. However, this is only an example for convenience, and the inventive concepts are not limited thereto. For example, portions of the common source line CSL respectively arranged in the memory cell area MEC and the connection area CON may be separated from each other. Alternatively, for example, the common source line CSL arranged in the memory cell area MEC may be a plurality of common source lines spaced apart from each other.

The stack structures may include the gate stack GS, in which the gate layers 130 are stacked on the common source line CSL, and a plurality of interlayer insulating layers 132. The interlayer insulating layers 132 may cover upper surfaces and lower surfaces of respective gate layers 130. The common source line CSL may be spaced apart from the peripheral circuit structure PCS with the stack structures therebetween. In other words, the stack structure may be structures in which the gate layers 130 are stacked alternately with the interlayer insulating layers 132.

In detail, the stack structures may each be stair-shaped. Horizontal areas (that is, areas on an X-Y plane) of the gate layers 130 and the interlayer insulating layers 132 may gradually decrease away from the common source line CSL. However, example embodiments are not limited thereto, and the horizontal areas of the gate layers 130 and the interlayer insulating layers 132 may gradually increase away from the common source line CSL. In this case, the connection area CON of the cell array structure CAS may be an area where the horizontal areas of the stack structures decrease, while the memory cell area may be an area where the horizontal areas of the stack structures are uniform.

A portion of the gate stack GS arranged in the memory cell area MEC may form the memory cell array MCA. The gate layers 130 included in the gate stack GS may be arranged in the memory cell area MEC, extend in a horizontal direction parallel to the common source line CSL, and overlap each other in the vertical direction (the Z direction).

In example embodiments, the gate layers 130 may include the word lines WL, the ground selection line GSL, and the string selection line SSL shown in FIG. 3.

In the memory cell array MCA, two string selection lines (e.g., SSL, see FIG. 3) that are adjacent to each other in the second horizontal direction (the Y direction) may be spaced apart from each other with a string selection line cut area SSLC. The string selection line cut area SSLC may be filled with an insulating layer 170. The insulating layer 170 may include an oxide layer, a nitride layer, or a combination thereof. In example embodiments, at least a portion of the string selection line cut area SSLC may be filled with an air gap. The term “air” used in the present specification may refer to the atmosphere or other gases that may exist during manufacture.

Each gate layer 130 may include a conductive pad area 112. The conductive pad area 112 may be a portion of the gate layer 130 that is arranged in the connection area CON of the cell array structure CAS. That is, a horizontal area of the conductive pad area 112 may decrease away from the common source line CSL. In other words, the conductive pad areas 112 may form stair-shaped connection portions in the connection area CON of the cell array structure CAS.

Each gate layer 130 may include metal, conductive metal nitride, or a combination thereof. For example, each gate layer 130 may include W, Ni, cobalt (Co), tantalum (Ta), tungsten nitride (WN), titanium nitride (TiN), tantalum nitride (TaN), or a combination thereof, but example embodiments are not limited thereto. The interlayer insulating layers 132 may each include silicon oxide, silicon nitride, or silicon oxynitride.

The channel structures 180 of the cell array structure CAS may be located in channel holes 180H, respectively. The channel hole 180H may penetrate the stack structures in the memory cell area. That is, the channel structures 180 may fill the inside of the channel holes 180H.

That is, in the memory cell area MEC, the channel structures 180 may extend in the vertical direction (the Z direction) by penetrating the stack structures and may be connected to the common source line CSL. The channel structures 180 may be spaced apart from each other in the first horizontal direction (the X direction) and the second horizontal direction (the Y direction) in certain intervals.

Each channel structure 180 may include a gate dielectric layer 182, a channel layer 184, a buried insulating layer 186, and a drain area 188. The gate dielectric layer 182 and the channel layer 184 may be sequentially arranged on the sidewalls of the channel hole 180H. For example, the gate dielectric layer 182 may be conformally arranged on the sidewalls of the channel hole 180H, and the channel layer 184 may be conformally arranged on the inner wall of the channel hole 180H. The buried insulating layer 186 may be arranged on the channel layer 184 to fill the remaining space of the channel hole 180H. In the drawing, the drain area 188 contacting the channel layer 184 and blocking the entrance of the channel hole 180H may be arranged on a lower portion of the channel hole 180H.

For example, the buried insulating layer 186 may include silicon oxide, silicon nitride, silicon oxynitride, or a combination thereof. In example embodiments, the buried insulating layer 186 may be omitted, and in this case, the channel layer 184 may have a pillar structure without inner space. The drain area 188 may include a metal silicide doped with impurities, metal, conductive metal nitride, or a combination thereof. Examples of metal forming the drain area 188 may include W, Ni, Co, Ta, and the like. The drain areas 188 may be insulated from each other by intermediate insulating layers 187. Each intermediate insulating layer 187 may include an oxide layer, a nitride layer, or a combination thereof.

FIG. 5 shows that the channel structure 180 includes the gate dielectric layer 182 and the gate dielectric layer 182 has a structure extending in the vertical direction (the Z direction) along the channel layer 184, but example embodiments are not limited thereto. Various modifications and changes may be made.

In the cell array structure CAS, the bit lines BL may be arranged on the channel structures 180. A plurality of bit line contact pads 194 may be arranged between the channel structures 180 and the bit lines BL. The drain area 188 of each channel structure 180 may be connected to a corresponding one of the bit lines BL through the bit line contact pad 194. The bit line contact pads 194 may be insulated from each other by a first lower insulating layer 193. The bit lines BL may be insulated from each other by a second lower insulating layer 195.

The bit line contact pads 194 and the bit lines BL may each include metal, metal nitride, or a combination thereof. For example, the bit line contact pads 194 and the bit lines BL may each include W, Ti, Ta, Cu, Al, TiN, TaN, WN, or a combination thereof. The first lower insulating layer 193 and the second lower insulating layer 195 may each include a silicon oxide layer, a silicon nitride layer, or a combination thereof.

In the cell array structure CAS, the bit lines BL may be connected to multiple circuits included in the peripheral circuit structure PCS through a wire structure MS and a bonding structure BS.

On the lower surface of the cell array structure CAS which is adjacent to the peripheral circuit structure PCS, a plurality of first bonding metal pads 178 may be arranged. The peripheral circuit structure PCS may include a plurality of second bonding metal pads 278 arranged on the multilayered wire structure MWS.

In the cell array structure CAS, the first bonding metal pads 178 may be respectively insulated by interlayer insulating layers 150. In the peripheral circuit structure PCS, the second bonding metal pads 278 may be respectively insulated by the interlayer insulating layers 70. The interlayer insulating layers 70 and 150 may each include a silicon oxide layer, a silicon nitride layer, or a combination thereof.

The second bonding metal pads 278 may be bonded to the first bonding metal pads 178 included in the cell array structure CAS and thus electrically connected thereto. The first bonding metal pads 178 and the second bonding metal pads 278 may form a plurality of bonding structures BS.

The first bonding metal pads 178 and the second bonding metal pads 278 forming the bonding structures BS may each include Cu, Al, or W.

In the cell array structure CAS, a connection insulating layer 114 covering the stair-shaped stack structures may be arranged between the common source line CSL and the intermediate insulating layer 187. The connection insulating layer 114 may include a silicon oxide layer, a silicon nitride layer, or a combination thereof.

In the connection area CON, a plurality of contact structures CTS penetrating the connection insulating layer 114 in the vertical direction (the Z direction) may be arranged on the conductive pad areas 112 that are portions of the gate layers 130. End portions of respective contact structures CTS may be connected to a plurality of wire layers ML arranged between the contact structures CTS and the peripheral circuit structure PCS. The wire layers ML may be arranged to penetrate a second lower insulating layer 195 at the same level as the bit lines BL.

The contact structures CTS may each include a contact plug 116 extending in the vertical direction (the Z direction). Sidewalls of the contact plug 116 may be surrounded by an insulating plug 115. The other end portion of the contact structure CTS may be electrically connected to the conductive pad area 112. As shown in FIG. 5, the wire structure MS may include a first upper wire layer 172, a second upper wire layer 174, and a third upper wire layer 176.

The contact plugs 116 included in the contact structures CTS and the first upper wire layer 172, the second upper wire layer 174, and the third upper wire layer 176, which are included in the wire structure MS, may each include W, Ti, Ta, Cu, Al, TiN, TaN, WN, or a combination thereof. In example embodiments, the bit lines BL may include the same materials as the wire layers ML.

In example embodiments, a plurality of dummy channel structures (not shown) penetrating the conductive pad areas 112 may be arranged in the connection area CON. The dummy channel structures may support the gate stack GS and the conductive pad areas 112, reducing or preventing undesired structural deformations, such as bending or breaking of portions of the gate stack GS and the conductive pad areas 112.

The gate layers 130 may be respectively connected to a plurality of circuits included in the peripheral circuit structure PCS through the conductive pad area 112, the contact structure CTS, the wire structure MS, and the bonding structure BS.

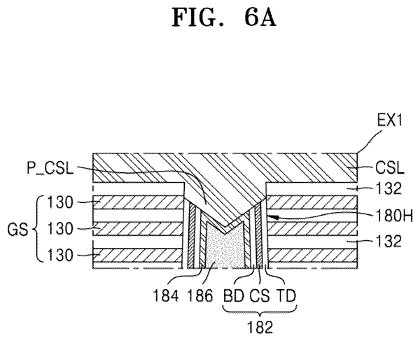

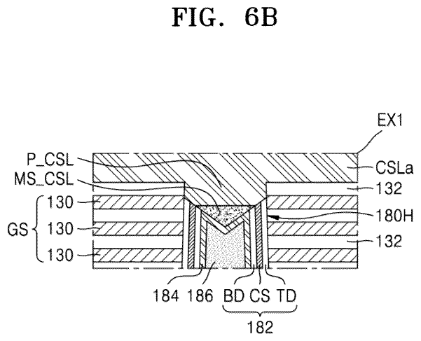

FIG. 6A is a cross-sectional view for explaining in detail the gate dielectric layer 182 and the common source line CSL of FIG. 5, and an enlarged cross-sectional view showing a region “EX1” of FIG. 5. Referring to FIG. 6A, the gate dielectric layer 182 and the common source line CSL are described in detail.

Referring to FIG. 6A, the gate dielectric layer 182 may include a tunneling dielectric layer TD, a charge storage layer CS, and a blocking dielectric layer BD which are sequentially formed from the channel layer 184. The tunneling dielectric layer TD may be arranged on the sidewalls forming the channel hole 180H, the blocking dielectric layer BD may be arranged on an outer wall of the channel layer 184, and the charge storage layer CS may be arranged between the tunneling dielectric layer TD and the blocking dielectric layer BD.

The tunneling dielectric layer TD may include silicon oxide, hafnium oxide, aluminum oxide, zirconium oxide, tantalum oxide, or the like. The charge storage layer CS may be a region in which electrons passing through the tunneling dielectric layer TD from the channel layer 184 may be stored, and may include silicon nitride, boron nitride, silicon boron nitride, or polysilicon doped with impurities. The blocking dielectric layer BD may include silicon oxide, silicon nitride, or metal oxide having greater permittivity than that of silicon oxide. The above metal oxide may include hafnium oxide, aluminum oxide, zirconium oxide, tantalum oxide, or a combination thereof.

The common source line CSL may include one surface contacting the stack structures and the other surface that is opposite to the surface. The common source line CSL may include a protrusion P_CSL on the surface contacting the stack structures. The common source line CSL may include the protrusion P_CSL protruding towards the inside of the channel hole 180H. That is, the protrusion P_CSL of the common source line CSL may be located inside the channel hole 180H. In example embodiments, the side surfaces of the protrusion P_CSL of the common source line CSL may be surrounded by the stack structures, and the lower surface of the protrusion P_CSL of the common source line CSL may contact the channel structure (e.g., 180, see FIG. 5). That is, the side surfaces of the protrusion P_CSL of the common source line CSL may contact the gate layer 130 and the interlayer insulating layer 132.

The common source line CSL may have a single-crystal structure and include, for example, single-crystal silicon. The protrusion P_CSL of the common source line CSL may be an epitaxially grown portion of the surface of the common source line CSL, which is exposed by the channel hole 180H. Accordingly, the protrusion P_CSL of the common source line CSL may also have a single-crystal structure like the common source line CSL. Moreover, the crystal orientation of the protrusion P_CSL of the common source line CSL may be the same as that of the common source line CSL. In example embodiments, a Miller index of the crystal orientation of the common source line CSL may be [1, 1, 1], and a Miller index of the crystal orientation of the protrusion P_CSL of the common source line CSL may be [1, 1, 1].

FIG. 6B is a cross-sectional view for explaining in detail the gate dielectric layer 182 and the common source line CSL of FIG. 5, and an enlarged cross-sectional view showing the region “EX1” of FIG. 5.

Referring to FIG. 6B, a common source line CSLa, which is different from the common source line (CSL, see FIG. 6A), is described in detail.

The common source line CSLa may include single-crystal silicon and an upper metal silicide MS_CSL. The upper metal silicide MS_CSL may be formed by performing annealing in a region where silicon contacts a metal, allowing the penetration of a metal component into silicon. That is, the upper metal silicide MS_CSL may be some portions of single-crystal silicon. The upper metal silicide MS_CSL may be a portion of the protrusion P_CSL of the common source line CSLa. In example embodiments, the upper metal silicide MS_CSL may be formed between the channel structure (e.g., 180, see FIG. 5) and single-crystal silicon. In the processes of manufacturing the semiconductor device 100, when metal is etched after depositing the metal in the channel hole 180H and then forming the upper metal silicide MS_CSL, the upper metal silicide MS_CSL may be located between the channel structure and the single-crystal silicon to contact an upper portion of the channel layer 184 of the channel structure.

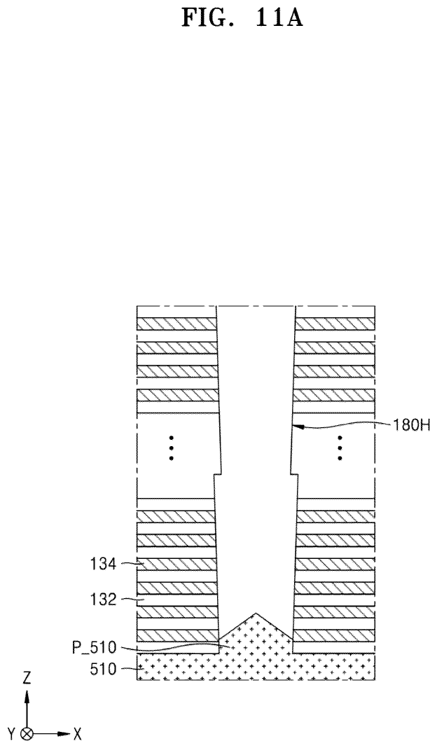

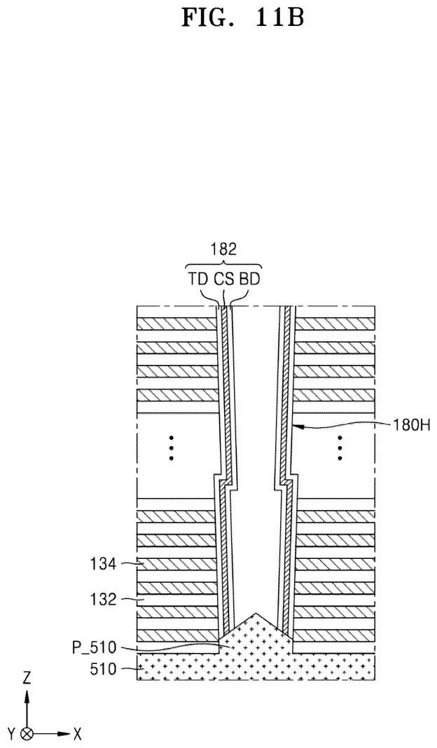

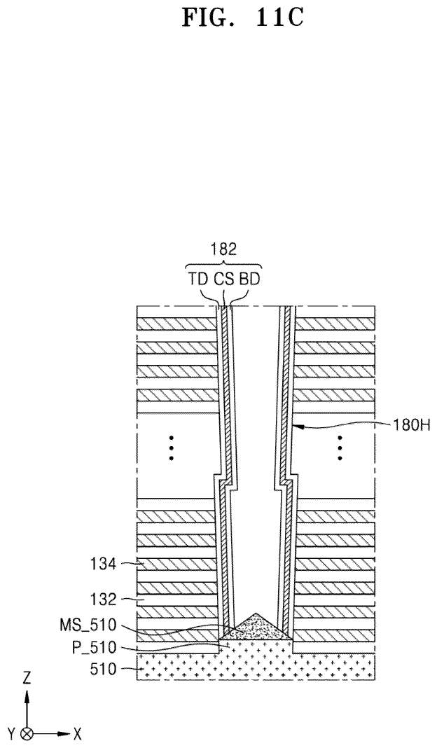

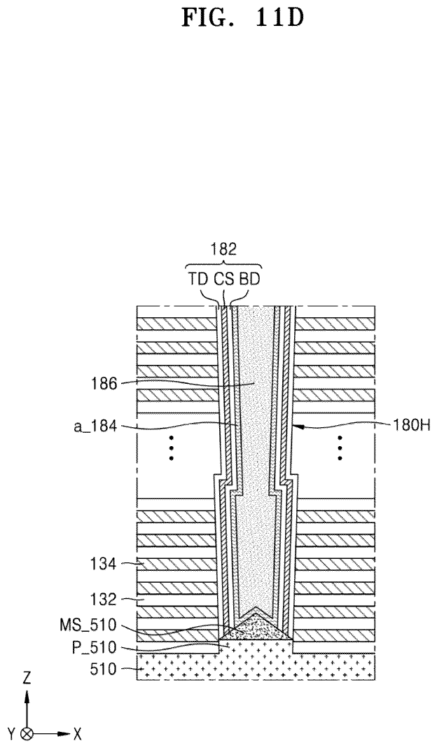

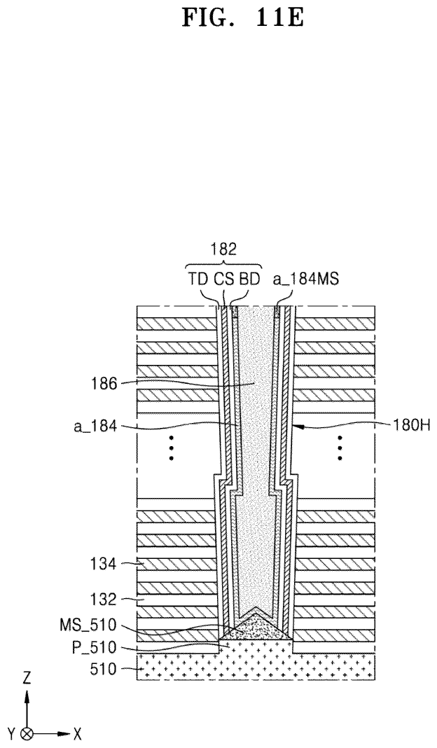

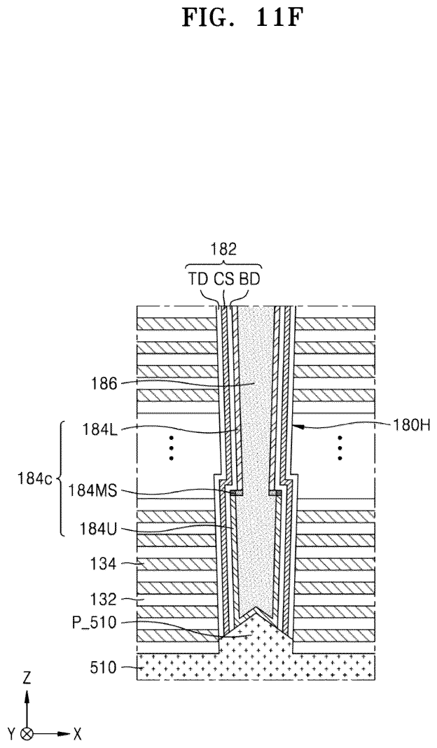

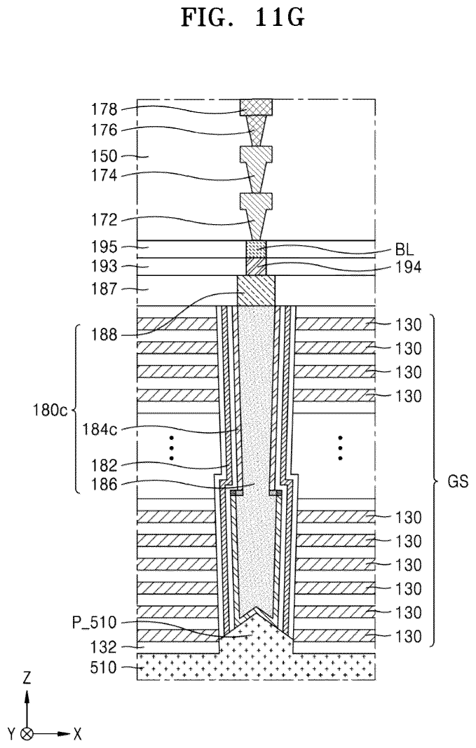

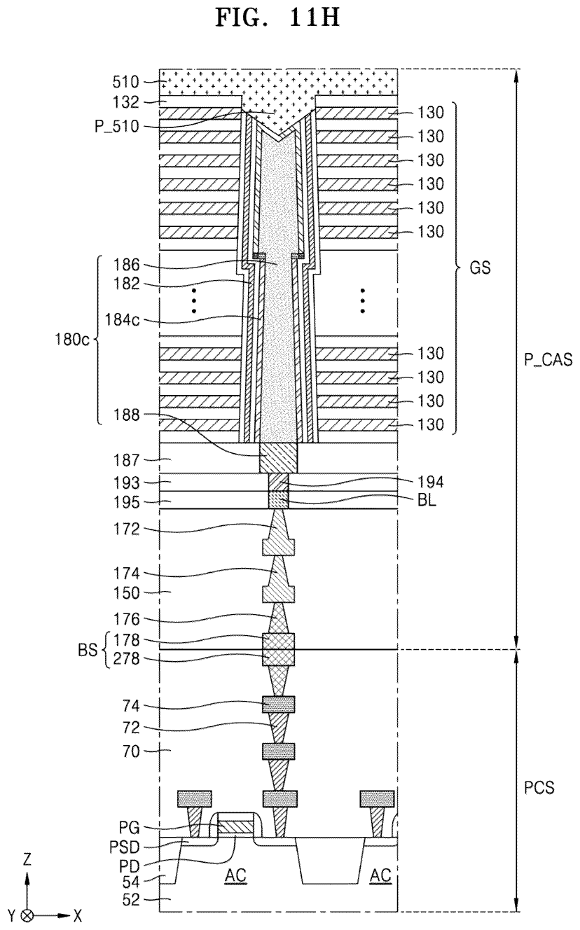

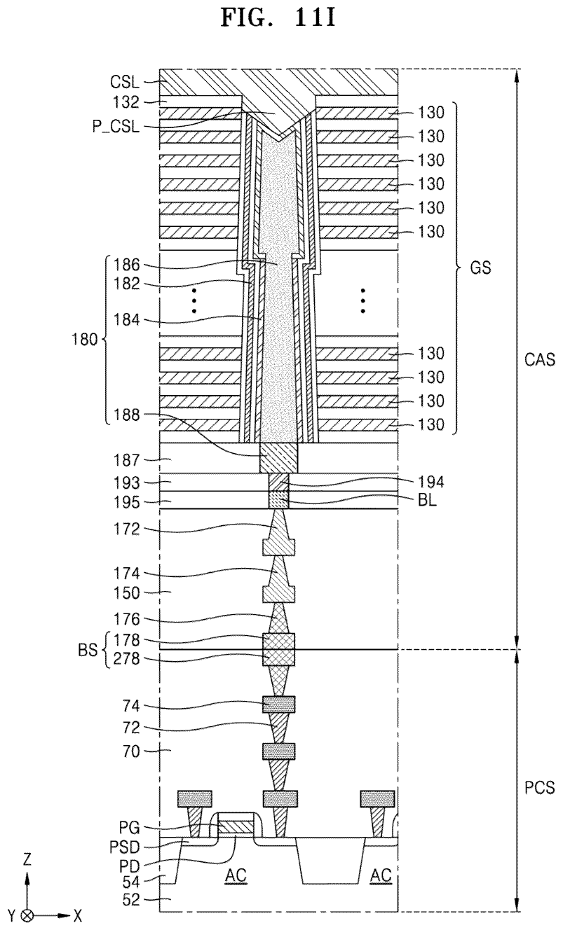

Although not shown in FIG. 6B, a lower metal silicide a_184MS (e.g., see FIG. 11E) may be located on a lower portion of the channel layer 184. In detail, the lower metal silicide a_184MS may contact the drain area (e.g., 188, see FIG. 5). That is, as a pair of metal silicide layers or areas may be provided as including upper metal silicide MS_CSL located on the upper portion of the channel layer 184 and lower metal silicide a_184MS on the lower portion of the channel layer 184, crystallization may proceed using the pair of metal silicide layers or areas as seeds of the channel layer 184.

In example embodiments, the upper metal silicide MS_CSL may be formed on single-crystal silicon, and the lower metal silicide may be formed on polycrystalline silicon or amorphous silicon. The upper metal silicide and the lower metal silicide may each include at least one of Ni, Co, Pd, Cu, Ta, and W.

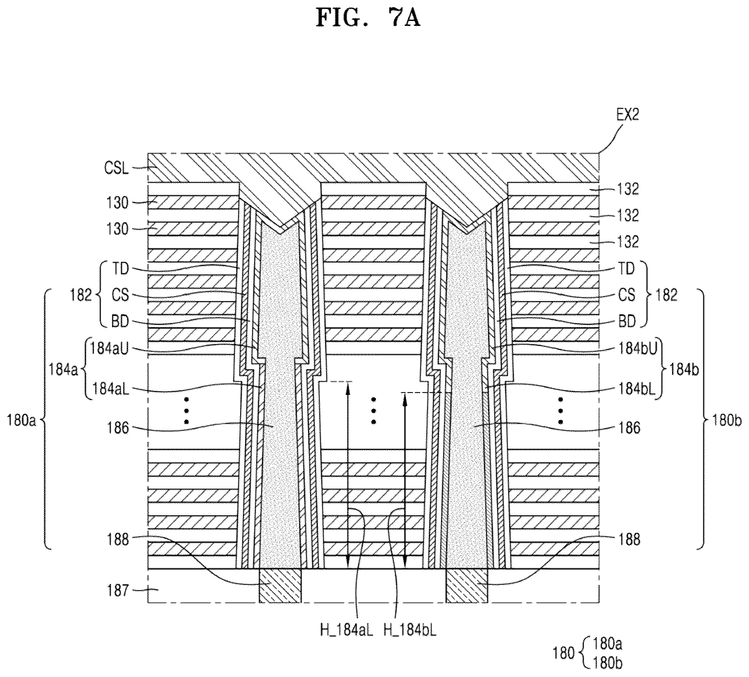

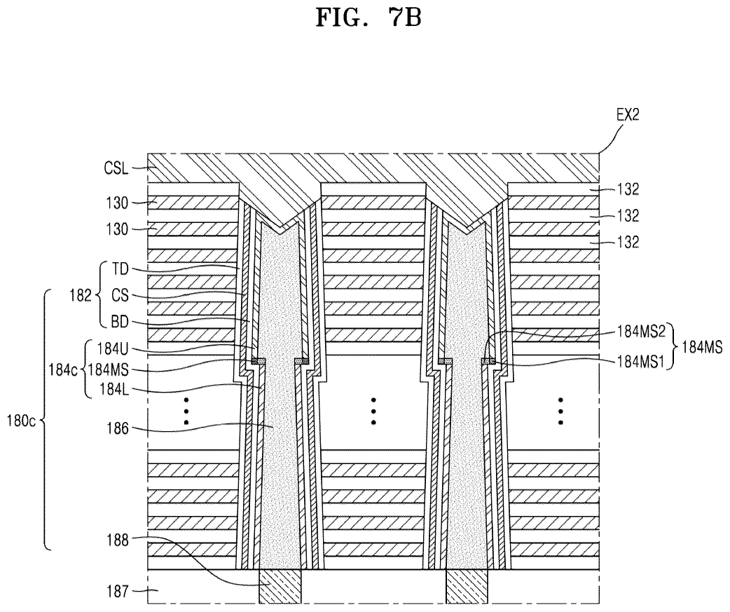

FIG. 7A is a cross-sectional view for explaining in detail the channel structures 180 of FIG. 5 and an enlarged cross-sectional view showing the region “EX2” of FIG. 5.

Referring to FIG. 7A, the channel structures 180, for example channel layers 184a and 184b, are described in detail.

The channel structures 180 of the semiconductor device 100 may extend in a vertical direction to penetrate the stack structures, respectively. Each channel structure 180 may include the gate dielectric layer 182, the channel layer 184, the buried insulating layer 186, and the drain area 188.

The channel layers 184a and 184b of the channel structures 180 may include upper channel layers 184aU and 184bU and lower channel layers 184aL and 184bL. The upper channel layers 184aU and 184bU may overlap on the lower channel layers 184aL and 184bL in the vertical direction. The upper channel layers 184aU and 184bU may contact the common source line CSL, and the lower channel layers 184aL and 184bL may be spaced apart from the common source line CSL with the upper channel layers 184aU and 184bU therebetween.

In example embodiments, upper portions of the upper channel layers 184aU and 184bU may contact the protrusion (e.g., P_CSL, see FIG. 6A) of the common source line CSL. Lower portions of the lower channel layers 184aL and 184bL may contact the intermediate insulating layer 187. The crystal orientation of the upper channel layers 184aU and 184bU may be the same as that of the protrusion of the common source line CSL.

The upper channel layers 184aU and 184bU and the lower channel layers 184aL and 184bL may each have a single-crystal structure. In detail, the upper channel layers 184aU and 184bU and the lower channel layers 184aL and 184bL may each include single-crystal silicon. The upper channel layers 184aU and 184bU and the lower channel layers 184aL and 184bL may have different crystal orientations. In example embodiments, the Miller index of the crystal orientations of the upper channel layers 184aU and 184bU may be [1, 1, 1], and the Miller index of the crystal orientations of the lower channel layers 184aL and 184bL may be [1, 0, 0].

While an amorphous channel layer (e.g., a_184, see FIG. 11E) is crystallized into the channel layer 184, the upper metal silicide (P_510, see FIG. 11E) serving as the seed of the upper channel layers 184aU and 184bU and the lower metal silicide (a_184MS, see FIG. 11E) serving as the seed of the lower channel layers 184aL and 184bL may be located on both sides spaced apart from each other in the vertical direction. The upper metal silicide is formed on single-crystal silicon, while the lower metal silicide is formed on amorphous silicon such that the crystal orientations of the upper channel layers 184aU and 184bU may be different from those of the lower channel layers 184aL and 184bL.

The channel structures 180 may include a first channel structure 180a and a second channel structure 180b. The first channel structure 180a may include a first channel layer 184a, and the second channel structure 180b may include a second channel layer 184b. The first channel layer 184a may include a first upper channel layer 184aU and a first lower channel layer 184aL, and the second channel layer 184b may include a second upper channel layer 184bU and a second lower channel layer 184bL.

The crystal orientation of the first upper channel layer 184aU of the first channel layer 184a may be the same as that of the second upper channel layer 184bU of the second channel layer 184b. The first upper channel layer 184aU and the second upper channel layer 184bU start to be crystallized from a portion contacting the common source line CSL having the single-crystal structure, and thus, the first upper channel layer 184aU and the second upper channel layer 184bU may have the same crystal orientations.

In example embodiments, the crystal orientation of the first lower channel layer 184aL of the first channel layer 184a may be different from that of the second lower channel layer 184bL of the second channel layer 184b. The first lower channel layer 184aL and the second lower channel layer 184bL may have different crystal orientations because the lower metal silicide is formed on a preliminary channel layer having an amorphous structure.

In example embodiments, a vertical length H_184aL of the first lower channel layer 184aL may be different from a vertical length H_184bL of the second lower channel layer 184bL. For example, the vertical length H_184aL of the first lower channel layer 184aL may be greater than the vertical length H_184bL of the second lower channel layer 184bL. Depending on the crystal orientation of a crystal structure, the crystallization rate may vary. Because the rates, at which the first lower channel layer 184aL and the second lower channel layer 184bL with different crystal orientations are formed, are different, the vertical length H_184aL of the first lower channel layer 184aL may differ from the vertical length H_184bL of the second lower channel layer 184bL.

FIG. 7B is a cross-sectional view for explaining in detail the channel structures 180 of FIG. 5 and an enlarged cross-sectional view showing the region “EX2” of FIG. 5.

Referring to FIG. 7B, a channel layer 184c that is different from the channel layers 184a and 184b is described in detail.

A channel structure 180c may include a channel layer 184c including a metal silicide 184MS. The metal silicide 184MS of the channel layer 184c may be located between an upper channel layer 184U and a lower channel layer 184L. That is, the upper channel layer 184U and the lower channel layer 184L of the channel layer 184c may be distinguished from each other based on the metal silicide 184MS. The upper channel layer 184U may be arranged between the metal silicide 184MS and the common source line CSL, and the lower channel layer 184L may be arranged between the metal silicide 184MS and the intermediate insulating layer 187. In example embodiments, the metal silicide 184MS of the channel layer 184c may include at least one of Ni, Co, Pd, Cu, Ta, and W.

The metal silicide 184MS of the channel layer 184c may be formed as a seed metal silicide moves or in other words meets together, in a process of forming the channel layer 184c. Crystallization is simultaneously performed on amorphous channel layers from seeds at both sides of the channel layer 184c, and thus, the metal silicide 184MS may be located in the middle of the channel layer 184c.

The metal silicide 184MS of the channel layer 184c may include an upper metal silicide 184MS2 and a lower metal silicide 184MS1. The upper metal silicide 184MS2 may contact the upper channel layer 184U, and the lower metal silicide 184MS1 may contact the lower channel layer 184L. Metal in the upper metal silicide 184MS2 may be different from that in the lower metal silicide 184MS1. The upper metal silicide may include the same component as an upper metal silicide (e.g., MS_510, see FIG. 11E) formed on a sub-substrate (e.g., 510, see FIG. 11E) including single-crystal silicon, and the lower metal silicide may include the same component as a lower metal silicide (e.g., a_184MS, see FIG. 11E) formed on amorphous silicon. However, example embodiments are not limited thereto, and the upper metal silicide 184MS2 may include the same metal as the lower metal silicide 184MS1.

FIG. 8 illustrates an electronic system including a semiconductor device, according to example embodiments.

Referring to FIG. 8, an electronic system 1000 may include a semiconductor device 1100 and a controller 1200 electrically connected to the semiconductor device 1100.

The electronic system 1000 may be a storage device including the semiconductor device 1100 or an electronic device including a storage device. For example, the electronic system 1000 may be a solid state drive (SSD) device, a universal serial bus (USB), a computing system, a medical device, or a communication device which includes at least one semiconductor device 1100.

The semiconductor device 1100 may be a non-volatile vertical memory device. For example, the semiconductor device 1100 may be a NAND flash memory device including at least one of the semiconductor devices 100 described above with reference to FIGS. 4 to 7B. The semiconductor device 1100 may include a first structure 1100F and a second structure 1100S on the first structure 1100F. In example embodiments, the first structure 1100F may be arranged next to the second structure 1100S.

The first structure 1100F may be a peripheral circuit structure including a decoder circuit 1110, a page buffer 1120, and a logic circuit 1130. The second structure 1100S may be a memory cell structure that includes a bit line BL, a common source line CSL, a plurality of word lines WL, first and second gate upper lines UL1 and UL2, first and second gate lower lines LL1 and LL2, and a plurality of memory cell strings CSTR arranged between the bit line BL and the common source line CSL.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT arranged between the lower transistors LT1 and LT2 and the upper transistors UT1 and UT2. The number of lower transistors LT1 and LT2 and the number of upper transistors UT1 and UT2 may vary according to embodiments.

In example embodiments, the upper transistors UT1 and UT2 may include string selection transistors, and the lower transistors LT1 and LT2 may include ground selection transistors. The gate lower lines LL1 and LL2 may be the gate electrodes of the lower transistors LT1 and LT2, respectively. The word line WL may be a gate electrode of the memory cell transistor MCT, and the gate upper lines UL1 and UL2 may be the gate electrodes of the upper transistors UT1 and UT2.

The common source line CSL, the gate lower lines LL1 and LL2, the word lines WL, and the gate upper lines UL1 and UL2 may be electrically connected to the decoder circuit 1110 through a plurality of first connection lines 1115 extending to the second structure 1100S in the first structure 1100F. The bit lines BL may be electrically connected to the page buffer 1120 through a plurality of second connection lines 1125 extending to the second structure 1100S in the first structure 1100F.

In the first structure 1100F, the decoder circuit 1110 and the page buffer 1120 may execute a control operation on at least one of the memory cell transistors MCT. The decoder circuit 1110 and the page buffer 1120 may be controlled by the logic circuit 1130.

The semiconductor device 1100 may communicate with the controller 1200 through input/output pads 1101 electrically connected to the logic circuit 1130. The input/output pad 1101 may be electrically connected to the logic circuit 1130 through input/output connection lines 1135 extending to the second structure 1100S in the first structure 1100F.

The controller 1200 may include a processor 1210, a NAND controller 1220, and a host interface 1230. In example embodiments, the electronic system 1000 may include a plurality of semiconductor devices 1100, and in this case, the controller 1200 may control the semiconductor devices 1100.

The processor 1210 may control the overall operation of the electronic system 1000 including the controller 1200. The processor 1210 may operate according to specific firmware and control the NAND controller 1220 to access the semiconductor device 1100. The NAND controller 1220 may include a NAND interface 1221 processing communication with the semiconductor device 1100. Through the NAND interface 1221, a control command for controlling the semiconductor device 1100, data to be written on the memory cell transistors MCT of the semiconductor device 1100, data to be read from the memory cell transistors MCT of the semiconductor device 1100, and the like may be transmitted. The host interface 1230 may provide a communication function between the electronic system 1000 and an external host. When receiving a control command from an external host through the host interface 1230, the processor 1210 may control the semiconductor device 1100 in response to the control command.

One or more of the elements disclosed above, such as for example the controller 1200, may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

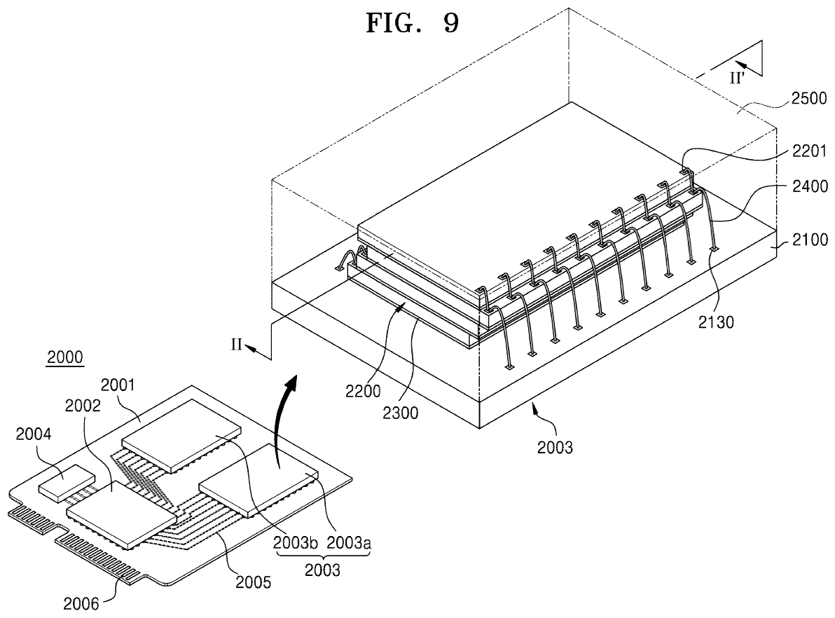

FIG. 9 is a perspective view of an electronic system including a semiconductor device, according to example embodiments.

Referring to FIG. 9, an electronic system 2000 according to example embodiments may include a main substrate 2001, a controller 2002 mounted on the main substrate 2001, one or more semiconductor packages 2003, and dynamic random access memory (DRAM) 2004. The semiconductor package 2003 and the DRAM 2004 may be connected to the controller 2002 by a plurality of wire patterns 2005 formed on the main substrate 2001.

The main substrate 2001 may include a connector 2006 including a plurality of pins coupled to the external host. The number and arrangements of pins in the connector 2006 may differ according to a communication interface between the electronic system 2000 and the external host. In example embodiments, the electronic system 2000 may communicate with the external host according to any one of interfaces, such as USB, Peripheral Component Interconnect Express (PCI_Express), Serial Advanced Technology Attachment (SATA), M-Phy for Universal Flash Storage (UFS) for Universal Flash Storage (UFS).

In example embodiments, the electronic system 2000 may operate by power supplied from the external host through the connector 2006. The electronic system 2000 may further include a Power Management Integrated Circuit (PMIC) configured to distribute power from the external host to the controller 2002 and the semiconductor package 2003.

The controller 2002 may write data to the semiconductor package 2003 or read data therefrom and may improve the operation speed of the electronic system 2000.

The DRAM 2004 may be a buffer memory for reducing a speed gap between the external host and the semiconductor package 2003 that is a data storage space. The DRAM 2004 included in the electronic system 2000 may also function as a cache memory and provide a space for temporarily storing data during a control operation performed on the semiconductor package 2003. When the electronic system 2000 includes the DRAM 2004, the controller 2002 may further include a DRAM controller to control the DRAM 2004, and the NAND controller for controlling the semiconductor package 2003.

The semiconductor package 2003 may include a first semiconductor package 2003a and a second semiconductor package 2003b that are spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, a plurality of semiconductor chips 2200 on the package substrate 2100, an adhesive layer 2300 arranged on a lower surface of each semiconductor chip 2200, a connection structure 2400 configured to electrically connect the semiconductor chips 2200 to the package substrate 2100, and a molding layer 2500 covering, on the package substrate 2100, the semiconductor chips 2200 and the connection structure 2400.

The package substrate 2100 may be a printed circuit board including a plurality of package upper pads 2130. Each semiconductor chip 2200 may include an input/output pad 2201. The input/output pad 2201 may correspond to the input/output pad (e.g., 1101, see FIG. 8). Each semiconductor chip 2200 may include at least one of the semiconductor devices 100 described above with reference to FIGS. 4 to 7B.

In example embodiments, the connection structure 2400 may be a bonding wire configured to electrically connect the input/output pad 2201 to the package upper pad 2130. Therefore, in the first semiconductor package 2003a and the second semiconductor package 2003b, the semiconductor chips 2200 may be electrically connected to each other in a bonding wire manner and electrically connected to the package upper pad 2130 of the package substrate 2100. In example embodiments, in the first semiconductor package 2003a and the second semiconductor package 2003b, the semiconductor chips 2200 may be electrically connected to each other by a connection structure including a TSV (not shown), instead of the connection structure 2400 that is the bonding wire.

In example embodiments, the controller 2002 and the semiconductor chips 2200 may be included in one package. In example embodiments, the controller 2002 and the semiconductor chips 2200 may be mounted on an interposer substrate that is different from the main substrate 2001 and may be connected to each other by a wire formed on the interposer substrate.

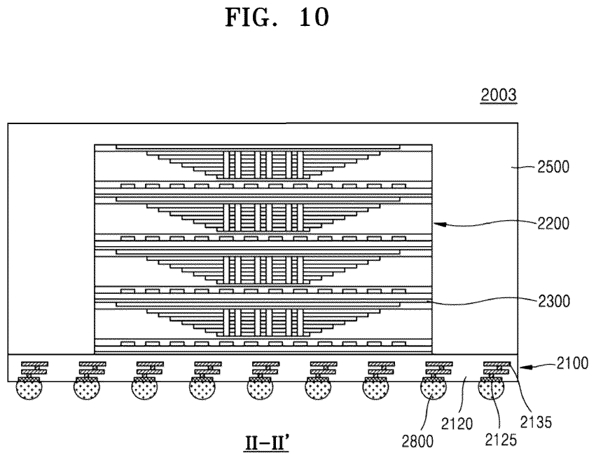

FIG. 10 is a cross-sectional view of a semiconductor package including a semiconductor device, according to example embodiments.

Referring to FIG. 10, in the semiconductor package 2003, the package substrate 2100 may be a printed circuit board.

The package substrate 2100 may include a body portion 2120, the package upper pad (e.g., 2130, see FIG. 9) arranged on the upper surface of the body portion 2120, a plurality of package lower pads 2125 arranged on or exposed through the lower surface of the body portion 2120, and an internal wire 2135 configured to electrically connect the package upper pad (e.g., 2130, see FIG. 9) to the package lower pad 2125 in the body portion 2120.

The package lower pads 2125 may be respectively connected to the wire patterns 2005 on the main substrate (e.g., 2001, see FIG. 9) through a plurality of conductive bumps 2800. Each semiconductor chip 2200 may include at least one of the semiconductor devices 100 described above with reference to FIGS. 4 to 7B.

FIGS. 11A to 11I are cross-sectional views illustrating, in a process order, a method of manufacturing a semiconductor device, according to example embodiments. Referring to FIGS. 11A to 11I, a method of manufacturing the semiconductor device 100 described above with reference to FIGS. 1 to 7B is described based on the memory cell area MEC.

Referring to FIG. 11A, the interlayer insulating layers 132 and a plurality of sacrificial insulating layers 134 may be alternately stacked one by one on the sub-substrate 510.

The sub-substrate 510 may include single-crystal silicon. The interlayer insulating layer 132 may each include a silicon oxide layer, and the sacrificial insulating layers 134 may each include a silicon nitride layer. Each sacrificial insulating layer 134 may be configured to secure a space for forming the gate stack (e.g., GS, see FIG. 5) in a subsequent process. Next, the channel holes 180H penetrating the interlayer insulating layers 132 and the sacrificial insulating layers 134 and extending in the vertical direction (the Z direction) may be formed.

In example embodiments, a plurality of preliminary channel holes may be formed in a first sub-substrate, and a plurality of preliminary channel holes may be formed in a second sub-substrate that is different from the first sub-substrate. Then, the channel holes 180H with relatively great aspect ratio may be formed by bonding the first sub-substrate to the second sub-substrate to enable the preliminary channel holes in the first sub-substrate to communicate with the preliminary channel holes in the second sub-substrate.

Then, a protrusion P_510 may be formed on the sub-substrate 510 exposed through the channel holes 180H, through selective epitaxial growth (SEG). The protrusion P_510 may be located inside each channel hole 180H. That is, the protrusion P_510 may contact the sacrificial insulating layer 134 and the interlayer insulating layer 132 by filling a portion of the inside of the channel holes 180H. The protrusion P_510 may be formed through epitaxial growth and have the same crystal orientation as the crystal orientation of the sub-substrate 510.

FIGS. 11B to 11E show processes of forming the upper metal silicide MS_510 and the lower metal silicide a_184MS on the protrusion P_510.

In each channel hole 180H, the gate dielectric layer 182 including the tunneling dielectric layer TD, the charge storage layer CS, and the blocking dielectric layer BD may be formed. Next, the lower surface of the gate dielectric layer 182 may be removed to expose the upper surface of the protrusion P_510 as shown in FIG. 11B. The gate dielectric layer 182 may be removed through wet etching. That is, because the gate dielectric layer 182 remains only on sidewalls forming the channel holes 180H, the protrusion P_510 having the single-crystal structure may be externally exposed.

Next, after the processing of FIG. 11B, a metal layer may be deposited to cover the upper surface of the protrusion P_510, and annealing may be performed at a temperature ranging from about 400° to about 600°, thereby forming the upper metal silicide MS_510 on a portion of the protrusion P_510. Then, the upper metal silicide MS_510 may be externally exposed by removing the metal layer. FIG. 11C shows upper metal silicide MS_510 after removal of the metal layer.

Next, a preliminary channel layer a_184 and the buried insulating layer 186 may be formed inside each of the channel holes 180H, as shown in FIG. 11D. The preliminary channel layer a_184 may have an amorphous structure. For example, the preliminary channel layer a_184 may include amorphous silicon.

Then, after the processing of FIG. 11D, a metal layer may be deposited to cover the upper surface of the preliminary channel layer a_184 and annealing is performed at a temperature ranging from about 400° to about 600°, thereby forming the lower metal silicide a_184MS on a portion of the preliminary channel layer a_184. Then, the metal layer may be removed, as shown in FIG. 11E.

The upper metal silicide MS_510 formed on the protrusion P_510 may include the same component as the lower metal silicide a_184MS formed on the preliminary channel layer a_184. For example, the upper metal silicide MS_510 and the lower metal silicide a_184MS may each include Ni.

Referring to FIGS. 11E and 11F, FIG. 11F shows a process of forming the channel layer 184 having the single-crystal structure by crystallizing the preliminary channel layer a_184 having the amorphous structure.

In example embodiments, the crystallization may be performed according to metal induced lateral crystallization (MILC).

When the crystallization is performed on the preliminary channel layer a_184 according to MILC, the crystallization may proceed by using each of the upper metal silicide MS_510 and the lower metal silicide a_184MS as a seed. That is, crystallization may be simultaneously performed on both sides of the preliminary channel layer a_184 to limit and/or prevent the crystallization from stopping, and/or to limit and/or prevent cracks from being formed in the crystallization. A portion of the channel layer 184, where crystallization starts on the upper metal silicide MS_510, may be the upper channel layer 184U, and a portion of the channel layer 184, where crystallization starts on the lower metal silicide a_184MS, may be the lower channel layer 184L.

The upper metal silicide MS_510 is formed on the sub-substrate 510 including single-crystal silicon, and thus, the upper channel layers 184U formed in the channel holes 180H may have the same crystal orientation. The lower metal silicide a_184MS is formed on the preliminary channel layer a_184 including amorphous silicon, and thus, the lower channel layers 184L formed in the channel holes 180H may have different crystal orientations. In example embodiments, the crystal orientation of the upper channel layer 184U formed in one channel hole 180H may be different from the crystal orientation of the lower channel layer 184L.

During the MILC, as the crystallization of the preliminary channel layer a_184 proceeds, a portion of the upper metal silicide MS_510 and a portion of the lower metal silicide a_184MS may move together, or in other words may meet. As a result, at a point at which the upper channel layer 184U meets the lower channel layer 184L, the metal silicide 184MS may be located, as shown in FIG. 11F.

FIG. 11G shows a process of forming the gate stack GS and a metal wire of a preliminary cell array structure P_CAS.

After the processing of FIG. 11F, the intermediate insulating layer 187 that covers a channel hole buried structure including the gate dielectric layer 182, the channel layer 184, and the buried insulating layer 186 may be formed, and a plurality of contact holes may be formed in the intermediate insulating layer 187. The upper surface of the channel hole buried structure is exposed through the contact holes, and the drain areas 188 are formed in the contact holes, thereby forming the channel structures 180.

Then, the word line cut areas (e.g., WLC, see FIG. 4) penetrating the interlayer insulating layers 132 and the sacrificial insulating layers 134 are formed, and the sacrificial insulating layers 134 may be substituted with the gate layers 130 through the word line cut areas WLC.

In some embodiments, to substitute the sacrificial insulating layers 134 with the gate layers 130, empty spaces between respective interlayer insulating layers 132 are prepared after selectively removing the sacrificial insulating layers 134 exposed through the word line cut areas (e.g., WLC, see FIG. 4), and then, conductive materials are filled into the empty spaces, thereby forming the gate layers 130, collectively shown as gate stack GS in FIG. 11G. Then, as shown in FIG. 4, the inside of each word line cut area WLC may be filled with the word line cut structure 192.

Next, after the first lower insulating layer 193 is formed on the channel structures 180 and the intermediate insulating layer 187, the bit line contact pads 194 penetrating the first lower insulating layer 193 and connected to the channel structures 180 may be formed in the memory cell area MEC. The intermediate insulating layer 187 and the first lower insulating layer 193 may form an insulating structure.

After the second lower insulating layer 195 is formed on the first lower insulating layer 193, the bit lines BL penetrating some regions of the second lower insulating layer 195 and connected to the bit line contact pads 194 may be formed.

Next, the wire structure, which includes the first upper wire layers 172, the second upper wire layers 174, and the third upper wire layers 176, the first bonding metal pads 178, and the interlayer insulating layer 150 filing gaps therebetween may be formed on the second lower insulating layer 195 and the bit lines BL.

FIGS. 11H and 11I show a process of bonding the preliminary cell array structure P_CAS to the peripheral circuit structure PCS and forming the common source line CSL.

As shown in FIG. 11H, the peripheral circuit structure PCS may be formed on the substrate 52 that is different from the sub-substrate 510 on which the preliminary cell array structure P_CAS is formed. In the substrate 52, active areas AC may be defined by the device isolation layer 54. The peripheral circuit structure PCS may include the gate dielectric layer PD and the gate PG which are sequentially stacked on the substrate 52 and a plurality of transistors including a plurality of ion implantation areas PSD and also include the above-described multilayered wire structure including the contact plugs 72 and the conductive lines 74. The interlayer insulating layer 70 of the peripheral circuit structure PCS may cover the transistors and the multilayered wire structure.

As shown in FIG. 11H, the first bonding metal pads 178 of the preliminary cell array structure P_CAS are bonded to the second bonding metal pads 278 included in the peripheral circuit structure PCS to form the bonding structures BS, thereby bonding the result of FIG. 11G onto the peripheral circuit structure PCS.

In example embodiments, the first bonding metal pads 178 may be directly bonded to the second bonding metal pads 278 by mutual pressure without a separate adhesive layer. For example, in a state in which the first bonding metal pads 178 face the second bonding metal pads 278, the first bonding metal pads 178 and the second bonding metal pads 278 are pressed in a direction, in which they get close to each other, to make the first bonding metal pads 178 and the second bonding metal pads 278 be coupled at an atomic level; thus, the bonding structures BS may be formed. In some embodiments, before the first bonding metal pads 178 are bonded to the second bonding metal pads 278, a process of surface-treating the exposed surfaces of the first bonding metal pads 178 and the exposed surfaces of the second bonding metal pads 278 with hydrogen plasma may be further performed to strengthen the adhesion thereof.

After the processing of FIG. 11H, the next process of forming the common source line CSL by doping the sub-substrate 510 is shown in FIG. 11I. Through ion implantation on the sub-substrate, n-type or s-type impurities may be implanted into single-crystal silicon. To this end, the cell array structure CAS including the common source line CSL may be formed. However, the method of forming the common source line CSL is not limited thereto. In example embodiments, the metal silicide 184MS of the channel layer 184 shown in FIG. 11F for example may also be removed.

While the inventive concepts have been particularly shown and described with reference to embodiments thereof, it will be understood that various changes in form and details may be made therein without departing from the spirit and scope of the following claims.

What is claimed is:

1. A semiconductor device comprising:
a peripheral circuit structure comprising a plurality of circuits; and
a cell array structure overlapping the peripheral circuit structure in a vertical direction,
wherein the cell array structure comprises
a common source line,
a stack structure comprising a plurality of gate layers and a plurality of interlayer insulating layers which are alternately stacked on the common source line, and
a plurality of channel structures in respective channel holes penetrating a memory cell area of the stack structure and connected to the common source line,
each of the plurality of channel structures comprises a channel layer including an upper channel layer and a lower channel layer each having a single-crystal structure, and
a crystal orientation of the upper channel layer is different from a crystal orientation of the lower channel layer.

2. The semiconductor device of claim 1, wherein in each of the plurality of channel structures the upper channel layer contacts the common source line, and
the lower channel layer is spaced apart from the common source line with the upper channel layer therebetween.

3. The semiconductor device of claim 1, wherein the common source line comprises a protrusion in a channel hole from among the channel holes.

4. The semiconductor device of claim 3, wherein each of the common source line and the protrusion of the common source line has a single-crystal structure.

5. The semiconductor device of claim 4, wherein a crystal orientation of the common source line and a crystal orientation of the protrusion of the common source line are the same.

6. The semiconductor device of claim 3, wherein the upper channel layer in the channel hole from among the channel holes contacts the protrusion of the common source line, and
the crystal orientation of the upper channel layer in the channel hole and a crystal orientation of the protrusion of the common source line are the same.

7. The semiconductor device of claim 1, wherein the common source line comprises single-crystal silicon and a metal silicide, and
the metal silicide is between the channel layer and the single-crystal silicon.

8. The semiconductor device of claim 1, wherein each of the plurality of channel structures further comprises a metal silicide, and
the metal silicide is between the upper channel layer and the lower channel layer.

9. The semiconductor device of claim 8, wherein the metal silicide comprises at least one of nickel (Ni), cobalt (Co), palladium (Pd), copper (Cu), tantalum (Ta), and tungsten (W).

10. The semiconductor device of claim 1, wherein the plurality of channel structures comprise a first channel structure and a second channel structure, and
a crystal orientation of an upper channel layer of the first channel structure and a crystal orientation of an upper channel layer of the second channel structure are the same.

11. The semiconductor device of claim 10, wherein a crystal orientation of a lower channel layer of the first channel structure is different from a crystal orientation of a lower channel layer of the second channel structure.

12. The semiconductor device of claim 10, wherein a length of a lower channel layer of the first channel structure in the vertical direction is different from a length of a lower channel layer of the second channel structure in the vertical direction.

13. A semiconductor device comprising:
a peripheral circuit structure comprising a plurality of circuits; and
a cell array structure overlapping the peripheral circuit structure in a vertical direction,
wherein the cell array structure comprises
a common source line,
a stack structure comprising a plurality of gate layers and a plurality of interlayer insulating layers which are alternately stacked on the common source line in a stair-shaped form, and
a plurality of channel structures in respective channel holes penetrating a memory cell area of the stack structure and contacting the common source line,
each of the plurality of channel structures comprises a channel layer comprising an upper channel layer and a lower channel layer each having a single-crystal structure,
the upper channel layers of the plurality of channel structures contact the common source line, and
crystal orientations of the upper channel layers of the plurality of channel structures are the same.

14. The semiconductor device of claim 13, wherein the crystal orientations of the upper channel layers of each of the plurality of channel structures are different from crystal orientations of the lower channel layers of the plurality of channel structures.

15. The semiconductor device of claim 13, wherein the lower channel layers of the plurality of channel structures are spaced apart from the common source line with the upper channel layers respectively therebetween, and
crystal orientations of the lower channel layers of the plurality of channel structures are different from each other.

16. The semiconductor device of claim 13, wherein the common source line is spaced apart from the peripheral circuit structure with the stack structure therebetween.

17. The semiconductor device of claim 16, wherein horizontal areas of the plurality of gate layers decrease away from the common source line.

18. The semiconductor device of claim 13, wherein the cell array structure further comprises a first bonding metal pad,
the peripheral circuit structure further comprises a second bonding metal pad, and
at least one of the plurality of gate layers is connected to at least one circuit of the plurality of circuits of the peripheral circuit structure through a bonding structure comprising the first bonding metal pad and the second bonding metal pad.

19. A semiconductor device comprising:
a peripheral circuit structure comprising a plurality of circuits and a first bonding metal pad; and
a cell array structure overlapping the peripheral circuit structure in a vertical direction,
wherein the cell array structure comprises,
a common source line having a single-crystal structure,
a stack structure comprising a plurality of gate layers and a plurality of interlayer insulating layers which are alternately stacked on the common source line in a stair-shaped form,
a plurality of channel structures in respective channel holes penetrating a memory cell area of the stack structure and contacting the common source line, and
a second bonding metal pad spaced apart from the common source line with the stack structure and the plurality of channel structures therebetween,
at least one of the plurality of circuits of the peripheral circuit structure is electrically connected to at least one of the plurality of gate layers of the cell array structure through the first bonding metal pad and the second bonding metal pad,
each of the plurality of channel structures comprises a channel layer comprising an upper channel layer and a lower channel layer each having a single-crystal structure,
each upper channel layer contacts the common source line,
each lower channel layer is spaced apart from the common source line with a respective upper channel layer therebetween, and
a crystal orientation of each upper channel layer and a crystal orientation of the common source line are the same, and the crystal orientation of each upper channel layer is different from a crystal orientation of each lower channel layer.

20. The semiconductor device of claim 19, wherein the plurality of channel structures comprise a first channel structure and a second channel structure,
a crystal orientation of a lower channel layer of the first channel structure is different from a crystal orientation of a lower channel layer of the second channel structure, and
a length of the lower channel layer of the first channel structure in the vertical direction is different from a length of the lower channel layer of the second channel structure in the vertical direction.
